(19) United States
(12) Patent Application Publication
(10) Pub. No.: US 2022/0153631 A1
(43) Pub. Date: May 19, 2022

(54) WAVELENGTH-CONVERSION MEMBER AND LIGHT-EMITTING DEVICE

(71) Applicant: NIPPON ELECTRIC GLASS CO., LTD., Otsu-shi, Shiga (JP)

(72) Inventors: Hiroyuki SHIMIZU, Otsu-shi (JP); Hideki ASANO, Otsu-shi (JP); Naoki UEDA, Otsu-shi (JP)

(21) Appl. No.: 17/430,415

(22) PCT Filed: Feb. 28, 2020
(86) PCT No.: PCT/JP2020/008261

§ 371 Date: Aug. 12, 2021

(30) Foreign Application Priority Data
Mar. 8, 2019 (JP) 2019-042162

(51) Int. Cl. C03C 4/12; F21V 9/30; C03C 3/091; C03C 3/093; C03C 3/095; C09K 11/77

(52) U.S. Cl. CPC C03C 4/12; F21V 9/30; C03C 3/091; C03C 2204/00; C03C 3/095; C09K 11/7774; C03C 3/093

(57) ABSTRACT

Provided is a wavelength conversion member that can easily reduce the leakage of excitation light in an ultraviolet range to the outside. A wavelength conversion member for use to convert excitation light having a wavelength of 250 to 280 nm to visible light contains a glass matrix and a phosphor dispersed in the glass matrix, and a total light transmittance of the glass matrix at a thickness of 1 mm is 0.1 to 80% at a wavelength of 250 to 280 nm.

### TECHNICAL FIELD

The present invention relates to wavelength conversion members for converting the wavelength of light emitted from a light source, such as a light emitting diode (LED) or a laser diode (LD), to another wavelength.

### BACKGROUND ART

Recently, attention has been increasingly focused on light-emitting devices using LEDs or LDs as next-generation light-emitting devices to replace fluorescence lamps and incandescent lamps, from the viewpoint of their low power consumption, small size, light weight, and easy adjustment to light intensity. For example, Patent Literature 1 discloses, as an example of such a light-emitting device, a light-emitting device in which a wavelength conversion member is disposed on an LED capable of emitting a blue light and absorbs part of the light from the LED to convert it to a yellow light. This light-emitting device emits a white light which is a synthetic light of the blue light emitted from the LED and the yellow light emitted from the wavelength conversion member.

As light-emitting devices using LEDs or LDs, other than those for use in general lightings, light-emitting devices for use in sensors are also proposed. For example, Patent Literature 2 discloses a light source for a methane gas sensor including: a light-emitting element capable of emitting ultraviolet light and/or visible light; and a phosphor layer provided on the light-emitting element.

### CITATION LIST

### Patent Literature

### [PTL 1]

JP-A-2000-208815

### [PTL 2]

JP-A-2013-170205

### SUMMARY OF INVENTION

### Technical Problem

If excitation light leaks together with fluorescence from the light-emitting device to the outside, this may have an adverse effect on the function as the sensor. Particularly, ultraviolet light is likely to have an adverse effect on human bodies when its wavelength is small. For this reason, in the light-emitting device described in Patent Literature 2, a filter blocking excitation light from passing therethrough but allowing fluorescence only to pass therethrough is formed on the surface of the phosphor layer. However, when such a filter is formed on the surface of the phosphor layer, there arises a problem that the production process becomes complicated, resulting in an increased cost.

In view of the foregoing, the present invention has an object of providing a wavelength conversion member that can easily reduce the leakage of excitation light in an ultraviolet range to the outside.

### Solution to Problem

A wavelength conversion member according to the present invention is a wavelength conversion member for use to convert excitation light having a wavelength of 250 to 280 nm to visible light and contains a glass matrix and a phosphor dispersed in the glass matrix, a total light transmittance of the glass matrix at a thickness of 1 mm being 0.1 to 80% at a wavelength of 250 to 280 nm. By limiting the total light transmittance of the glass matrix in the wavelength conversion member to a value as low as 80% or less, it can be reduced that ultraviolet excitation light having not been converted in wavelength leaks to the outside. On the other hand, by limiting the total light transmittance of the glass matrix in the wavelength conversion member to 0.1% or more, ultraviolet excitation light can be prevented from being excessively absorbed into the glass matrix, so that a desired luminous efficiency can be achieved.

In the wavelength conversion member according to the present invention, the glass matrix preferably contains, in terms of % by mole, 30 to 85% SiO₂, 0 to 35% B₂O₃, 0 to 25% Al₂O₃, 0 to 7% Li₂O+Na₂O+K₂O, and 0 to 45% MgO+CaO+SrO+BaO. By limiting the composition of the glass matrix as just described, the desired total light transmittance as described above can be easily achieved. Note that, herein, “(component)+(component)+ . . . ” means the total content of the relevant components.

In the wavelength conversion member according to the present invention, the glass matrix preferably contains, in terms of % by mole, 0.001 to 10% CeO₂. Thus, it can be reduced that ultraviolet excitation light leaks to the outside of the wavelength conversion member.

A wavelength conversion member according to the present invention is a wavelength conversion member for use to convert excitation light having a wavelength of 250 to 280 nm to visible light and contains a glass matrix and a phosphor dispersed in the glass matrix, the glass matrix containing, in terms of % by mole, 30 to 85% SiO₂, 0 to 35% B₂O₃, 0 to 25% Al₂O₃, 0 to 7% Li₂O+Na₂O+K₂O, and 0 to 45% MgO+CaO+SrO+BaO.

In the wavelength conversion member according to the present invention, the phosphor is preferably a garnet-based phosphor.

In the wavelength conversion member according to the present invention, the phosphor is preferably Lu₃Al₅O₁₂: Ce.

In the wavelength conversion member according to the present invention, a content of the phosphor is preferably 0.01 to 70% by volume.

The wavelength conversion member according to the present invention is preferably made of a sintered body containing: a glass powder being a source material for the glass matrix; and the phosphor. Thus, a wavelength conversion member with the phosphor uniformly dispersed therein can be easily produced.

A light-emitting device according to the present invention includes: the above-described wavelength conversion member; and a light source operable to irradiate the wavelength conversion member with excitation light having a wavelength of 250 to 280 nm.

In the light-emitting device according to the present invention, in terms of a spectrum of light emitted from the wavelength conversion member, a relationship 0≤I₁/I₂≤0.2 is preferably satisfied between I₁ representing a peak intensity derived from the excitation light and I₂ representing a peak intensity derived from fluorescence emitted from the phosphor. Thus, a light-emitting device can be obtained which has a desired luminescence intensity and in which the leakage of ultraviolet excitation light to the outside is reduced.

In the light-emitting device according to the present invention, preferably, I₁/I₂=0. Thus, a high-safety light-emitting device having no leakage of ultraviolet excitation light to the outside can be obtained.

### Advantageous Effects of Invention

The present invention enables provision of a wavelength conversion member that can easily reduce the leakage of excitation light in an ultraviolet range to the outside.

### BRIEF DESCRIPTION OF DRAWINGS

FIG. 1 is a schematic side view showing a light-emitting device according to an embodiment of the present invention.

### DESCRIPTION OF EMBODIMENTS

A wavelength conversion member according to the present invention is a wavelength conversion member for use to convert excitation light having a wavelength of 250 to 280 nm to visible light and contains a glass matrix and a phosphor dispersed in the glass matrix.

The total light transmittance of the glass matrix at a thickness of 1 mm to light having a wavelength of 250 to 280 nm is 0.1 to 80%, preferably 0.5 to 80%, more preferably 0.6 to 50%, still more preferably 0.8 to 30%, yet still more preferably 1 to 20%, and particularly preferably 1.2 to 12%. If the total light transmittance of the glass matrix is too low, excitation light is excessively absorbed into the glass matrix, so that a desired luminous efficiency is less likely to be achieved. On the other hand, if the total light transmittance of the glass matrix is too high, ultraviolet excitation light having not been converted in wavelength is likely to leak to the outside.

An example of the glass matrix is one containing, in terms of % by mole, 30 to 85% SiO₂, 0 to 35% B₂O₃, 0 to 25% Al₂O₃, 0 to 7% Li₂O+Na₂O+K₂O, and 0 to 45% MgO+CaO+SrO+BaO. Reasons why the glass composition is limited as just described will be described below. In the following description of each component, “%” refers to “% by mole” unless otherwise stated.

SiO₂ is a component that forms the glass network and has the effect of increasing the ultraviolet ray transmittance and the devitrification resistance. Furthermore, SiO₂ also has the effect of increasing the weather resistance and the mechanical strength. The content of SiO₂ is preferably 30 to 85%, more preferably 40 to 80%, still more preferably 50 to 75%, and particularly preferably 55 to 70%. If the content of SiO₂ is too small, the above effects are less likely to be obtained. On the other hand, if the content of SiO₂ is too large, the sintering temperature becomes high, so that the phosphor is likely to degrade during production of the wavelength conversion member. Furthermore, the fluidity of glass powder during firing becomes poor, so that bubbles are likely to remain in the glass matrix after the firing. In addition, the ultraviolet ray transmittance may be excessively high.

B₂O₃ is a component that lowers the melting temperature to significantly improve the meltability. Furthermore, B₂O₃ has the effect of not lowering the ultraviolet ray transmittance much and reducing ultraviolet ray absorption of alkali metal components and alkaline earth metal components. The content of B₂O₃ is preferably 0 to 35%, more preferably 0 to 20%, still more preferably 1 to 15%, yet still more preferably 2 to 10%, even yet still more preferably 3 to 8%, and particularly preferably 4 to 7%. If the content of B₂O₃ is too large, the weather resistance is likely to decrease. In addition, the ultraviolet ray transmittance may be excessively high.

Al₂O₃ is a component that increases the weather resistance and the mechanical strength. Furthermore, Al₂O₃ has, like B₂O₃, the effect of reducing ultraviolet ray absorption of alkali metal components and alkaline earth metal components. The content of Al₂O₃ is preferably 0 to 25%, more preferably 0.1 to 20%, still more preferably 1 to 10%, and particularly preferably 2 to 8%. If the content of Al₂O₃ is too large, the meltability tends to decrease. In addition, the ultraviolet ray transmittance may be excessively high.

Li₂O, Na₂O, and K₂O are components that lower the melting temperature to improve the meltability and lower the softening point. However, if the content of these component is too large, the weather resistance is likely to decrease and the luminescence intensity is likely to be decreased with time by irradiation of excitation light. Therefore, the content of Li₂O+Na₂O+K₂O is preferably 0 to 7%, more preferably 0 to 5%, still more preferably 0 to 3%, yet still more preferably 0 to 2%, and particularly preferably 0 to 1%, and the glass composition is most preferably free from these components. Furthermore, the content of each of Li₂O, Na₂O, and K₂O is preferably 0 to 7%, more preferably 0 to 5%, still more preferably 0 to 3%, yet still more preferably 0 to 2%, and particularly preferably 0 to 1%, and the glass composition is most preferably free from each component.

As will be described hereinafter, when the glass composition contains CeO₂, the decrease in luminescence intensity with time due to irradiation of excitation light can be reduced even if the glass composition contains Li₂O, Na₂O or K₂O. Therefore, when the glass composition contains CeO₂, the glass composition may positively contain Li₂O, Na₂O or K₂O. In this case, the content (total content) of Li₂O, Na₂O, and K₂O is preferably 0.1 to 7%, more preferably 1 to 6.5%, and still more preferably 2 to 6%. Furthermore, the content of each of Li₂O, Na₂O, and K₂O is preferably 0 to 7%, more preferably 0.1 to 5%, still more preferably 0.5 to 4%, and particularly preferably 1 to 3%. Li₂O, Na₂O, and K₂O are preferably used in a mixture of two or more of them and particularly preferably used in a mixture of all the three components. Specifically, the glass composition contains each of Li₂O, Na₂O, and K₂O in a content of preferably 0.1% or more, more preferably 0.5% or more, and particularly preferably 1% or more. Thus, the softening point can be efficiently lowered by a mixed alkali effect. Furthermore, the mixed alkali effect can be easily obtained by making the respective contents of the alkali oxides equal.

MgO, CaO, SrO, and BaO are components that lower the melting temperature to improve the meltability and lower the softening point. These components have, unlike the alkali metal components, no effect in terms of decrease in luminescence intensity with time in the wavelength conversion member. The content of MgO+CaO+SrO+BaO is preferably 0 to 45%, more preferably 1 to 45%, still more preferably 5 to 40%, yet still more preferably 10 to 35%, and particularly preferably 20 to 33%. If the content of MgO+CaO+SrO+BaO is too small, the softening point is less likely to decrease. On the other hand, if the content of MgO+CaO+SrO+BaO is too large, the weather resistance is likely to decrease. The content of each component of MgO, CaO, SrO, and BaO is preferably 0 to 35%, more preferably 0.1 to 33%, and particularly preferably 1 to 30%. If the content of each of these components is too large, the weather resistance tends to decrease.

ZnO is a component that lowers the melting temperature to improve the meltability. The content of ZnO is preferably 0 to 15%, more preferably 0 to 10%, still more preferably 0 to 5%, yet still more preferably 0.1 to 4.5%, and particularly preferably 1 to 4%. If the content of ZnO is too large, the weather resistance tends to decrease. Furthermore, phase separation tends to occur to decrease the transmittance and, as a result, the luminescence intensity tends to decrease.

CeO₂ is a component that decreases the ultraviolet ray transmittance of the glass matrix. By containing CeO₂ in the glass matrix, the leakage of ultraviolet excitation light to the outside of the wavelength conversion member can be reduced. Furthermore, CeO₂ has the effect of reducing the decrease in luminescence intensity with time due to Li₂O, Na₂O or K₂O. The content of CeO₂ is preferably 0 to 10%, more preferably 0.001 to 10%, still more preferably 0.001 to 5%, yet still more preferably 0.01 to 3%, even yet still more preferably 0.05 to 1%, and particularly preferably 0.1 to 0.5%. If the content of CeO₂ is too large, the visible light transmittance of the glass matrix tends to decrease to decrease the luminescence intensity.

In addition to the above components, various components can be contained in the glass composition without impairing the effects of the present invention. For example, P₂O₅, La₂O₃, Ta₂O₅, TeO₂, TiO₂, Nb₂O₅, Gd₂O₃, Y₂O₃, Sb₂O₃, SnO₂, Bi₂O₃, As₂O₃, ZrO₂, and so on may be contained in the glass composition, each in a content of 15% or less, preferably 10% or less, particularly preferably 5% or less, and within a range of up to 30% in total. Moreover, F can be contained in the composition. Because F has the effect of lowering the softening point, the incorporation of F in substitution for an alkali metal component becoming a contributor to formation of color centers enables reduction of the decrease in luminescence intensity with time while enabling the maintenance of a low softening point. The content of F is, in terms of % by anion, preferably 0 to 10%, more preferably 0 to 8%, and particularly preferably 0.1 to 5%.

The softening point of the glass matrix is preferably 600 to 1100° C., more preferably 630 to 1050° C., and particularly preferably 650 to 1000° C. If the softening point of the glass matrix is too low, the mechanical strength and weather resistance are likely to decrease. On the other hand, if the softening point is too high, the sintering temperature accordingly becomes high, which makes the phosphor likely to degrade in the firing process during production.

The average particle diameter D₅₀ of a glass powder being a source material for the glass matrix is preferably 100 μm or less, more preferably 50 μm or less, still more preferably 20 μm or less, and particularly preferably 10 μm or less. If the average particle diameter D₅₀ of the glass powder is too large, bubbles are likely to remain in the glass matrix after firing in the resultant wavelength conversion member, so that the light extraction efficiency of the wavelength conversion member may decrease. The lower limit of the average particle diameter D₅₀ of the glass powder is not particularly limited, but is preferably not less than 0.1 μm, more preferably not less than 1 μm, and particularly preferably not less than 2 μm in consideration of the production cost and the handleability. Note that in the present invention the average particle diameter D₅₀ refers to a value measured by laser diffractometry.

There is no particular limitation as to the type of phosphor so long as it emits fluorescence in a visible range (for example, with a wavelength of 500 to 600 nm) when irradiated with excitation light having a wavelength of 250 to 280 nm, and examples include an oxide phosphor, a nitride phosphor, an oxynitride phosphor, a chloride phosphor, an oxychloride phosphor, a halide phosphor, an aluminate phosphor, and a halophosphoric acid chloride phosphor. Among them, a garnet phosphor, particularly Lu₃Al₅O₁₂: Ce, a sialon phosphor, particularly Si_{6-z}Al_{z}O_{z}N_{8-z}: Eu (0<z<4.2) (β-SiALON: Eu), and so on are preferred because they can efficiently convert excitation light having a wavelength of 250 to 280 nm to fluorescence in a visible range.

The luminous efficiency (lm/W) of the wavelength conversion member varies depending on the type and content of the phosphor, the thickness of the wavelength conversion member, and so on. The content of the phosphor and the thickness of the wavelength conversion member may be appropriately adjusted so that the luminous efficiency and the fluorescence intensity become optimal. For example, when the thickness of the wavelength conversion member is small, the content of the phosphor may be increased so that a desired luminous efficiency and a desired fluorescence intensity can be obtained. However, if the content of the phosphor is too large, the wavelength conversion member may have problems, such as: it is less likely to be sintered; it has a large porosity to thus make it less likely that the phosphor is efficiently irradiated with excitation light; and the mechanical strength of the wavelength conversion member decreases. On the other hand, if the content of the phosphor is too small, a desired fluorescence intensity is difficult to achieve. From these perspectives, the content of the phosphor in the wavelength conversion member according to the present invention is preferably 0.01 to 70% by volume, more preferably 0.05 to 50% by volume, and still more preferably 0.08 to 30% by volume.

The wavelength conversion member according to the present invention is, for example, made of a sintered body containing: a glass powder being a source material for the glass matrix; and a phosphor (phosphor powder). The firing temperature of a mixed powder containing the glass powder and the phosphor is preferably in a range of the glass powder softening point plus/minus 150° C. and particularly preferably in a range of the glass powder softening point plus/minus 100° C. If the firing temperature is too low, the glass powder does not sufficiently flow, so that a dense sintered body is difficult to obtain. On the other hand, if the firing temperature is too high, the phosphor component may thermally degrade to decrease the luminescence intensity.

The firing is preferably performed in a reduced-pressure atmosphere. Specifically, the atmosphere during firing is preferably less than 1.013×10⁵ Pa, more preferably 1000 Pa or less, and particularly preferably 400 Pa or less. Thus, the amount of bubbles remaining in the wavelength conversion member can be reduced and, for the reason described previously, the luminescence intensity can be increased. The whole firing process may be performed in a reduced-pressure atmosphere or only the firing step of the process may be performed in a reduced-pressure atmosphere and the temperature increasing step and temperature decreasing step before and after the firing step may be performed in an atmosphere other than the reduced-pressure atmosphere (for example, under an atmospheric pressure).

There is no particular limitation as to the form of the wavelength conversion member according to the present invention and examples include not only members themselves having specific shapes, such as platy, columnar, hemispherical, and hemispherical dome shapes, but also, for example, film-like sintered bodies formed on surfaces of base materials, including a glass substrate and a ceramic substrate.

An antireflection film or a concavo-convex microstructure layer may be provided on the surface of the wavelength conversion member. In this way, the light reflectance at the surface of the wavelength conversion member can be reduced, so that the light extraction efficiency can be improved and the luminescence intensity can be thus increased.

An example of the antireflection film is a monolayer or multilayer film (dielectric multilayer film) made of an oxide, a nitride, a fluoride or the like and the film can be formed by sputtering, vapor deposition, coating, or so on. The light reflectance of the antireflection film is, in a wavelength range of 380 to 780 nm, preferably 5% or less, more preferably 4% or less, and particularly preferably 3% or less.

The wavelength conversion member may be a laminate composed of a wavelength conversion layer containing a phosphor and a glass layer containing no phosphor. Thus, the glass layer serves as an antireflection film, so that the light extraction efficiency can be increased. As the glass layer, a glass powder sintered body or a bulk glass can be used. The glass for use as the glass layer preferably has the same composition as a glass for use as the wavelength conversion layer and, thus, the light reflectance loss at the interface between the wavelength conversion layer and the glass layer can be reduced.

An example of the concavo-convex microstructure layer is a moth eye structure having a size equal to or smaller than the wavelengths of visible light. Examples of a production method for the concavo-convex microstructure layer include nanoimprint lithography and photolithography. Alternatively, the concavo-convex microstructure layer can be formed by roughening the surface of the wavelength conversion member by sandblasting, etching, polishing or the like. The surface roughness Ra of the concavo-convex structure layer is preferably 0.001 to 0.3 μm, more preferably 0.003 to 0.2 μm, and particularly preferably 0.005 to 0.15 μm. If the surface roughness Ra is too small, a desired antireflection effect is difficult to achieve. On the other hand, if the surface roughness Ra is too large, light scattering is significant, so that the luminescence intensity is likely to decrease.

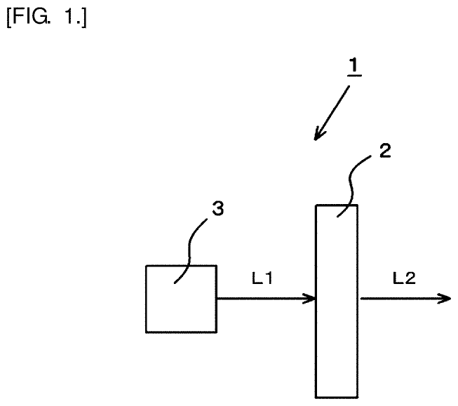

FIG. 1 shows an example of an embodiment of a light-emitting device according to the present invention. As shown in FIG. 1, the light-emitting device 1 includes a wavelength conversion member 2 and a light source 3. The light source 3 irradiates the wavelength conversion member 2 with excitation light L1. The excitation light L1 with a wavelength of 250 to 280 nm having entered the wavelength conversion member 2 is converted to fluorescence L2 in a visible range and exits from the opposite side of the wavelength conversion member 2 to the light source 3.

In this situation, the relationship 0≤I₁/I₂≤0.2 is preferably satisfied between the peak intensity I₁ derived from the excitation light L1 and the peak intensity I₂ derived from the fluorescence L2. Thus, a light-emitting device can be obtained which has a desired luminescence intensity and in which the leakage of ultraviolet excitation light to the outside is reduced. From the viewpoint of reducing the leakage of ultraviolet excitation light to the outside, the value of I₁/I₂ is preferably 0.15 or less, particularly preferably 0.1 or less, and most preferably 0. From the viewpoint of maximizing the luminescence intensity of the fluorescence L2, it is preferred that part of the excitation light L1 is not converted in wavelength, but passes through the wavelength conversion member 2 as it is. Specifically, the value of I₁/I₂ is preferably over 0 to 0.1 and particularly preferably 0.01 to 0.05.

### Examples

Hereinafter, the present invention will be described in detail with reference to examples, but the present invention is not limited to these examples.

Tables 1 and 2 show working examples (Nos. 1 to 9, 11, and 12) of the present invention and a comparative example (No. 10).

TABLE 1

| | Glass Composition (% by mole) | | 1 | 2 | 3 | 4 | 5 | 6 | 7 | 8 | 9 | 10 |
|---|---|---|---|---|---|---|---|---|---|---|---|---|
| GLASS | SiO₂ | | 61 | 69.5 | 68 | 66 | 60 | 48.5 | 53.5 | 49.5 | 62.5 | 68 |
| MATRIX | Al₂O₃ | | 4 | 10.4 | 10.5 | 12.5 | 17 | 3.5 | 1.5 | 1.5 | 10 | 4 |
| | B₂O₃ | | 5 | 9.5 | 9.5 | 7 | 9 | 5 | 5 | 6.5 | 7 | 19 |
| | Na₂O | | | | | | | | | | 1 | 7 |
| | K₂O | | | | | | | | | | | 1 |
| | MgO | | | | | 5 | | 21.5 | | | 8.5 | |
| | CaO | | 16 | 9.5 | 9.5 | 7 | 8 | | 9.5 | 9.5 | 6 | |
| | SrO | | | 0.5 | 0.5 | 0.5 | 5 | 3.5 | 4 | 4.5 | | |
| | BaO | | 12 | 0.4 | 1 | 2 | 1 | 12 | 15.5 | 16 | 4.8 | |
| | ZnO | | 2 | | 0.8 | | | | | | | |
| | TiO₂ | | | | | | | 4 | 6.5 | 7 | | |
| | ZrO₂ | | | | | | | 2 | 2 | 1.5 | | |
| | La₂O₃ | | | | | | | | 2.5 | 4 | | |
| | Sb₂O₃ | | | 0.2 | 0.2 | | | | | | 0.2 | |
| | F₂ | | | | | | | | | | | 1 |
| | L₂O + Na₂O + K₂O | | 0 | 0 | 0 | 0 | 0 | 0 | 0 | 0 | 1 | 8 |
| | MgO + CaO + SrO + BaO | | 28 | 10.4 | 11 | 14.5 | 14 | 37 | 29 | 30 | 19.3 | 0 |
| | Softening Point (° C.) | | 850 | 984 | 984 | 987 | 969 | 829 | 834 | 818 | 912 | 695 |
| | Total Light Transmittance | Minimum | 1.6 | 64.1 | 55.8 | 43.5 | 50.5 | 0.9 | 1.3 | 1.1 | 17.1 | 85.3 |
| | (%) at 250 to 280 nm | Maximum | 10.6 | 75.1 | 72.5 | 68.4 | 69.5 | 6.1 | 8.1 | 7.5 | 28.5 | 91.4 |

| | | | | | | | | | | |
|---|---|---|---|---|---|---|---|---|---|---|
| I₁/I₂ | 0.002 | 0.18 | 0.16 | 0.14 | 0.15 | 0 | 0.001 | 0.001 | 0.05 | 0.25 |

TABLE 2

| | Glass Composition (% by mole) | | 11 | 12 |
|---|---|---|---|---|
| GLASS | SiO₂ | | 45 | 45 |
| MATRIX | Al₂O₃ | | 4 | 4 |
| | B₂O₃ | | 18 | 18 |
| | Li₂O | | 1.5 | 1.5 |
| | Na₂O | | 1.5 | 1.5 |
| | K₂O | | 1.5 | 1.5 |
| | MgO | | | |
| | CaO | | | |
| | SrO | | | |
| | BaO | | 25 | 25 |
| | ZnO | | 3.5 | 3.25 |
| | CeO₂ | | | 0.25 |
| | L₂O + Na₂O + K₂O | | 4.5 | 4.5 |
| | MgO + CaO + SrO + BaO | | 25 | 25 |
| | Softening Point (° C.) | | 683 | 683 |
| | Total Light Transmittance | Minimum | 39.5 | 0.3 |
| | (%) at 250 to 280 nm | Maximum | 65.2 | 0.4 |

| | | |
|---|---|---|
| I₁/I₂ | 0.12 | 0 |

Raw materials were formulated to give each of the glass compositions described in the tables and each resultant mixture was melted at 1200 to 1700° C. for one to two hours using a platinum crucible to vitrify it. The molten glass was run through between a pair of cooling rollers to form it into a film shape. The obtained film-like formed glass body was ground in a ball mill and then classified, thus obtaining a glass powder having an average particle diameter D₅₀ of 2.5 μm.

The softening point of the glass was measured using the fiber elongation method, and a temperature at which the viscosity reached 10^{7.6} dPa·s was employed as the softening point.

In measuring the total light transmittance of the glass, the molten glass was formed to produce a sample with a thickness of 1 mm and the sample was measured by the method in accordance with JIS K7105.

A powder of Lu₃Al₅O₁₂: Ce phosphor (fluorescence peak wavelength: 560 nm) was mixed into the obtained glass powder and the mixed powder was fired at a temperature of a glass softening point plus 50° C., thus obtaining a sintered body. The phosphor powder was mixed into the glass powder so that the content thereof in the wavelength conversion member became 10% by volume. The sintered body was processed, thus obtaining a wavelength conversion member having a thickness of 1 mm.

The wavelength conversion member was irradiated with light from a mercury lamp (with a wavelength of 254 nm) and the spectral energy distribution of light emitted from the light exit surface of the wavelength conversion member was measured with a general-purpose emission spectral measurement device. From the obtained spectra, the ratio I₁/I₂ between the peak intensity I₁ of excitation light and the peak intensity I₂ of fluorescence was determined. The results are shown in Tables 1 and 2.

As shown in Tables 1 and 2, in Nos. 1 to 9, 11 and 12 which are working examples, the value of I₁/I₂ was 0 to 0.18, which shows that the leakage of ultraviolet ray to the outside could be reduced. On the other hand, in No. 10 which is a comparative example, the value of I₁/I₂ was 0.25, which shows that the leakage of ultraviolet rays to the outside was large.

### REFERENCE SIGNS LIST

1 light-emitting device
2 wavelength conversion member
3 light source

1. A wavelength conversion member for use to convert excitation light having a wavelength of 250 to 280 nm to visible light, the wavelength conversion member containing a glass matrix and a phosphor dispersed in the glass matrix, a total light transmittance of the glass matrix at a thickness of 1 mm being 0.1 to 80% at a wavelength of 250 to 280 nm.

2. The wavelength conversion member according to claim 1, wherein the glass matrix contains, in terms of % by mole, 30 to 85% SiO₂, 0 to 35% B₂O₃, 0 to 25% Al₂O₃, 0 to 7% Li₂O+Na₂O+K₂O, and 0 to 45% MgO+CaO+SrO+BaO.

3. The wavelength conversion member according to claim 1, wherein the glass matrix contains, in terms of % by mole, 0.001 to 10% CeO₂.

4. A wavelength conversion member for use to convert excitation light having a wavelength of 250 to 280 nm to visible light, the wavelength conversion member containing a glass matrix and a phosphor dispersed in the glass matrix, the glass matrix containing, in terms of % by mole, 30 to 85% SiO₂, 0 to 35% B₂O₃, 0 to 25% Al₂O₃, 0 to 7% Li₂O+Na₂O+K₂O, and 0 to 45% MgO+CaO+SrO+BaO.

5. The wavelength conversion member according to claim 1, wherein the phosphor is a garnet-based phosphor.

6. The wavelength conversion member according to claim 5, wherein the phosphor is Lu₃Al₅O₁₂: Ce.

7. The wavelength conversion member according to claim 1, wherein a content of the phosphor is 0.01 to 70% by volume.

8. The wavelength conversion member according to claim 1, being made of a sintered body containing: a glass powder being a source material for the glass matrix; and the phosphor.

9. A light emitting device comprising: the wavelength conversion member according to claim 1; and a light source operable to irradiate the wavelength conversion member with excitation light having a wavelength of 250 to 280 nm.

10. The light-emitting device according to claim 9, wherein, in terms of a spectrum of light emitted from the wavelength conversion member, a relationship 0≤I₁/I₂≤0.2 is satisfied between I₁ representing a peak intensity derived from the excitation light and I₂ representing a peak intensity derived from fluorescence emitted from the phosphor.

11. The light-emitting device according to claim 10, wherein I₁/I₂=0.
